(19) United States
(12) Patent Application Publication
(10) Pub. No.: US 2006/0097799 A1
(43) Pub. Date: May 11, 2006

(54) CMOS balanced colpitts oscillator

(76) Inventor: Pierre Paul Guebels, Pleasanton, CA (US)

Correspondence Address: ROSENBERG, KLEIN & LEE, 3458 ELLICOTT CENTER DRIVE-SUITE 101, ELLICOTT CITY, MD, 21043, US

(21) Appl. No.: 10/972,351

(22) Filed: Oct. 26, 2004

(51) Int. Cl. H03K 3/03

(52) U.S. Cl. 331/46

(57) ABSTRACT

A CMOS Balanced Colpitts oscillator which benefits from low cost CMOS technology. By overcoming the limited transconductance of CMOS transistors to permit oscillation with a crystal, the Balanced Colpitts application is expanded beyond simple VCO designs and permits crystal oscillator applications. The crystal is connected between the gates of the transistors of each Colpitts oscillator. The crystal supplies a differential frequency signal to both oscillators, which is a half period phase difference. In this way, the circuit effectively doubles the frequency signal. Further optimization is achieved by including variable capacitors in the circuit. In this way, the oscillation frequency can be adjusted by a control voltage, thus realizing a voltage controlled crystal oscillator. The present invention overcomes the challenge of adequately designing the varicaps in order to optimize the VCXO performance while not increasing the crystal load capacitance which would make the oscillation more difficult to start.

### BACKGROUND OF THE INVENTION

1. Field of the Invention

The present invention relates to an oscillator. More specifically, the present invention discloses a CMOS Balanced Colpitts oscillator that benefits from low cost CMOS technology for cost reduction and increased affordability of design.

2. Description of the Prior Art

The need for higher frequency reference signals has exacerbated the importance of frequency multiplication circuits that preserve phase noise at an affordable cost.

While Phase Locked Loops (PLL) are widely used, a PLL's phase noise performance is mainly limited to that of its voltage control oscillator (VCO). For phase noise and jitter sensitive applications, non-PLL frequency multiplication is required, in particular frequency doublers.

One type of frequency doubler uses a mixer to derive the higher frequency and filter out the subharmonics and undesired harmonics. For example, taking advantage of the harmonic products that result from a non-linear amplifier. However, these solutions only achieve limited harmonic and subharmonic rejection.

Other disadvantages to conventional approaches are designs that only exist in Bipolar (BJT and HBT) transistors and are not available in CMOS technology and existing designs address VCO designs and not crystal oscillators.

Therefore there is need for an improved oscillator that is realized in CMOS technology and thereby more affordable due to the lower cost.

### SUMMARY OF THE INVENTION

To achieve these and other advantages and in order to overcome the disadvantages of the conventional method in accordance with the purpose of the invention as embodied and broadly described herein, the present invention provides a CMOS Balanced Colpitts oscillator that benefits from low cost CMOS technology for cost reduction and increased affordability of design.

The present invention exploits the properties of a Balanced Colpitts oscillator by applying it to CMOS technology.

By overcoming the limited transconductance of CMOS transistors to permit oscillation with a crystal, the Balanced Colpitts application is expanded beyond simple VCO designs and permits crystal oscillator applications.

Further optimization is achieved by including variable capacitors (varicaps) in the circuit. As a result, the oscillation frequency can be adjusted by a control voltage, thus realizing a voltage controlled crystal oscillator (VCXO).

The present invention overcomes the challenge of adequately designing the varicaps in order to optimize the VCXO performance while not increasing the crystal load capacitance that would make the oscillation more difficult to start.

The CMOS Balanced Colpitts oscillator of the present invention basically comprises two oscillator circuits configured in a balanced configuration. Additionally, a crystal oscillator is connected between the gates of the transistors of both oscillator circuits.

The crystal oscillator provides a reference frequency to the oscillators. The reference frequency supplied to the first oscillator is a half period out of phase with the frequency supplied to the second oscillator. The drains of the transistors of each oscillator are connected together and this node will see the sum of the currents through each oscillator. As a result, the circuit of the present invention effectively doubles the reference frequency of the crystal oscillator.

Furthermore, a filter is provided to filter out any direct current (DC) component present and to further attenuate higher frequency harmonics.

Additionally, variable capacitors are utilized in both oscillator circuits. A control voltage input tunes the variable capacitors which adjusts the oscillation frequency.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a circuit schematic illustrating a Balanced Colpitts crystal oscillator according to an embodiment of the present invention; and

FIG. 2 is a circuit schematic illustrating a Balanced Colpitts voltage controlled crystal oscillator according to an embodiment of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

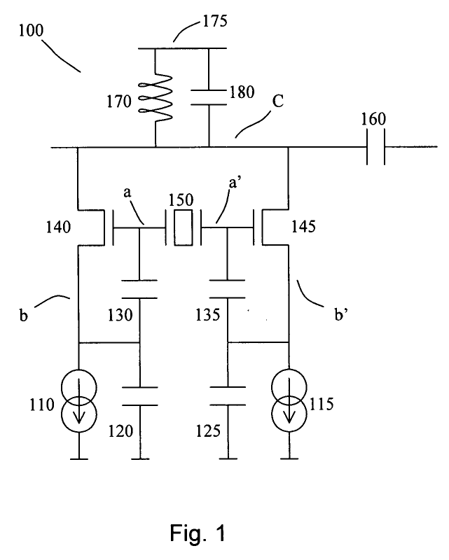

Refer to FIG. 1, which is a circuit schematic illustrating a Balanced Colpitts crystal oscillator according to an embodiment of the present invention.

As shown in FIG. 1, the oscillator circuit 100 comprises a crystal oscillator 150 electrically connected between the gates of a first transistor 140 and a second transistor 145. A first capacitor 130 is connected between the gate and the source of the first transistor 140. A first current source 110 is connected to the source of the first transistor 140 and to ground. A second capacitor 120 is connected in parallel with the first current source 110.

A third capacitor 135 is connected between the gate and the source of the second transistor 145. A second current source 115 is connected to the source of the second transistor 145 and to ground. A fourth capacitor 125 is connected in parallel with the second current source 115.

A filter 175, comprising an inductor 170 and a fifth capacitor 180 connected in parallel, is connected to the drains of the first transistor 140 and the second transistor 145. The filter 175 filters out the DC component present and further attenuates higher frequency harmonics.

A sixth capacitor 160 couples the oscillator circuit 100 to the next stage through AC coupling.

Now that the circuitry has been described, the operation and theory of the invention will be described.

A differential reference frequency signal is applied to (a) and (a′). In other words, the same periodic signal is applied with half a period phase difference.

The circuit is dimensioned so that the magnitude of the currents through (b) and (b′) are equal. Let Ib(t) and Ib′(t) denote these currents respectively. These period currents, which are half a period apart, can be expresses as follows using Fourier decomposition:

$$Ib ( t ) = {\sum }_{k} {Ib}_{k} {ⅇ}^{j k ( 2 π ) / {T}^{*} t}$$

$${Ib}^{′} ( t ) = {\sum }_{k} {Ib}_{k}^{′} {ⅇ}^{j k ( 2 π ) / {T}^{*} [ t - T / 2 ]}$$

From the circuit topology as shown in FIG. 1, node (c) sees the sum of these two currents. Since Ib(t) and Ib(t) are equal in magnitude, Ib=Ib′ₖ, for all k.

Hence, let Ic denote the sum of Ib(t) and Ib′(t) that is seen on node (c). This can be written in the following equation:

$$Ic ( t ) = {\sum }_{k} {Ib}_{k} {ⅇ}^{j k ( 2 π ) / {T}^{*} t} * [ 1 + {ⅇ}^{j k π} ]$$

Because e^{jkπ}=−1 for all odd k values,

$${Ib}_{k} {ⅇ}^{j k ( 2 π ) / {T}^{*} t} * [ 1 + {ⅇ}^{j k π} ] = 0$$

if k is odd. This can be rewritten for only considering the even values of k as:

$$Ic ( t ) = {\sum }_{{k}^{′}} {Ib}_{{k}^{′}} {ⅇ}^{j {k}^{′} ( 2 π ) / {T}^{′ *} t}$$

by writing k′ as k′=k/2, and T′=T/2.

This effectively is a frequency doubling of the original reference signal. The doubled frequency can be passed on the next stage through AC coupling (capacitor 160).

A filter 175 comprising an inductor 170 and a capacitor 180, is present to filter out the DC component present in Ic(t), and further attenuates higher frequency harmonics.

Furthermore, the CMOS design is such that it will permit the oscillation of a crystal placed between (a) and (a′) thus constituting a crystal oscillator with doubling of frequency, or in other words a frequency doubler.

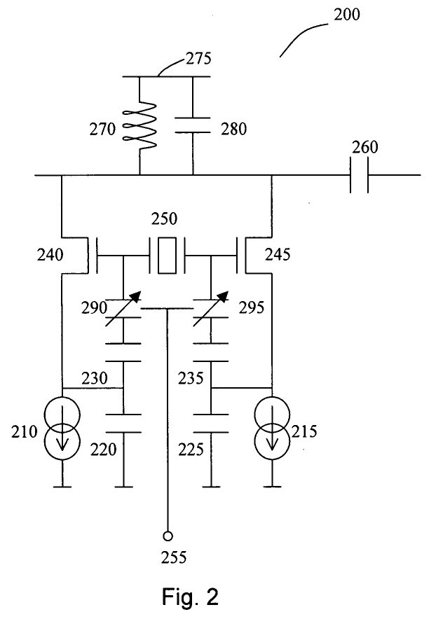

Refer to FIG. 2, which is a circuit schematic illustrating a Balanced Colpitts voltage controlled crystal oscillator according to an embodiment of the present invention.

The oscillator circuit 200 illustrated in FIG. 2, is similar to the circuit of FIG. 1, with the addition of a first varicap 290 connected between the first capacitor 230 and the gate of the first transistor 240, and a second varicap 295 connected between the third capacitor 235 and the gate of the second transistor 245.

In the voltage controlled crystal oscillator implementation as shown in FIG. 2, the varicaps 290, 295 are tuned by a control voltage applied to the control voltage input 255 which adjusts the oscillation frequency, thus realizing a VCXO.

In other words, by increasing or decreasing the voltage level of the control voltage, a corresponding change in the capacitance of the variable capacitors is achieved. As a result, the change in capacitance of the variable capacitors affects the oscillation frequency.

The present invention efficiently provides a circuit that can be utilized as a frequency doubler, a balanced oscillator applied to crystal oscillators, and a voltage controlled crystal oscillator.

The circuit utilizes CMOS technology which lowers costs making design easier and less expensive. Additionally, the present invention provides a frequency multiplication circuit which preserves phase noise at an affordable cost.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. An oscillator circuit comprising:
a first Colpitts oscillator;
a second Colpitts oscillator; and
a crystal oscillator connected between the first Colpitts oscillator and the second Colpitts oscillator.

2. The oscillator circuit of claim 1, the first Colpitts oscillator comprising:
a first transistor comprising a first gate, a first source, and a first drain;
a first capacitor connected between the first gate and the first source of the first transistor;
a first current source connected between the first source of the first transistor and ground; and
a second capacitor connected in parallel with the first current source.

3. The oscillator circuit of claim 2, the second Colpitts oscillator comprising:
a second transistor comprising a second gate, a second source, and a second drain;
a third capacitor connected between the second gate and the second source of the second transistor;
a second current source connected between the second source of the second transistor and ground; and
a fourth capacitor connected in parallel with the second current source.

4. The oscillator circuit of claim 3, further comprising:
a filter connected to the first drain of the first transistor and the second drain of the second transistor.

5. The oscillator circuit of claim 4, the filter comprising an inductor and a fifth capacitor connected in parallel.

6. The oscillator circuit of claim 1, further comprising:
a sixth capacitor to couple the oscillator circuit to a next stage through AC coupling.

7. The oscillator circuit of claim 3, wherein the first capacitor and the third capacitor are variable capacitors.

8. The oscillator circuit of claim 7, further comprising a control voltage for tuning the variable capacitors to adjust oscillation frequency.

9. The oscillator circuit of claim 1, wherein an output of the oscillator circuit is double the crystal oscillator frequency.

10. A balanced Colpitts oscillator comprising:
a first transistor comprising a first gate, a first source, and a first drain;
a second transistor comprising a second gate, a second source, and a second drain;
a crystal oscillator electrically connected between the first gate of the first transistor and the second gate of the second transistor;
a first capacitor connected between the first gate and the first source of the first transistor;
a first current source connected between the first source of the first transistor and ground;
a second capacitor connected in parallel with the first current source;
a third capacitor connected between the second gate and the second source of the second transistor;
a second current source connected between the second source of the second transistor and ground; and
a fourth capacitor connected in parallel with the second current source.

11. The balanced Colpitts oscillator of claim 10, further comprising:
a filter connected to the first drain of the first transistor and the second drain of the second transistor.

12. The balanced Colpitts oscillator of claim 11, the filter comprising an inductor and a fifth capacitor connected in parallel.

13. The balanced Colpitts oscillator of claim 10, further comprising:
a sixth capacitor to couple the balanced Colpitts oscillator to a next stage through AC coupling.

14. The balanced Colpitts oscillator of claim 10, wherein the first capacitor and the third capacitor are variable capacitors.

15. The balanced Colpitts oscillator of claim 14, further comprising a control voltage for tuning the variable capacitors to adjust oscillation frequency.

16. The balanced Colpitts oscillator of claim 10, wherein the balanced Colpitts oscillator doubles the frequency of the crystal oscillator.

17. A balanced Colpitts oscillator comprising:
a first transistor comprising a first gate, a first source, and a first drain;
a second transistor comprising a second gate, a second source, and a second drain;
a crystal oscillator electrically connected between the first gate of the first transistor and the second gate of the second transistor;
a first variable capacitor connected to the first gate;
a first capacitor connected between the first variable capacitor and the first source of the first transistor;
a first current source connected between the first source of the first transistor and ground;
a second capacitor connected in parallel with the first current source;
a second variable capacitor connected to the second gate;
a third capacitor connected between the second variable capacitor and the second source of the second transistor;
a second current source connected between the second source of the second transistor and ground;
a fourth capacitor connected in parallel with the second current source;
a filter connected to the first drain of the first transistor and the second drain of the second transistor; and
a sixth capacitor to couple the balanced Colpitts oscillator to a next stage through AC coupling.

18. The balanced Colpitts oscillator of claim 17, the filter comprising an inductor and a fifth capacitor connected in parallel.

19. The balanced Colpitts oscillator of claim 17, further comprising a control voltage for tuning the variable capacitors to adjust oscillation frequency.

20. The balanced Colpitts oscillator of claim 17, wherein the balanced Colpitts oscillator doubles the frequency of the crystal oscillator.
